(19) United States
(12) Patent Application Publication
(10) Pub. No.: US 2005/0218504 A1
(43) Pub. Date: Oct. 6, 2005

(54) FILLED CAVITIES SEMICONDUCTOR DEVICES

(75) Inventors: Timothy J. Dalton, Ridgefield, CT (US); John A. Fitzsimmons, Poughkeepsie, NY (US); Anthony K. Stamper, Williston, VT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 10/708,883

(22) Filed: Mar. 30, 2004

(51) Int. Cl. H01L 21/311; H01L 23/14

(52) U.S. Cl. 257/702

(57) ABSTRACT

In an embodiment of the invention, a dielectric material comprises a matrix of a material selected from the group consisting essentially of organic materials, inorganic materials and organo-silicate materials; a plurality of pores dispersed throughout the matrix; and a gas filling the pores. The gas is selected from the group consisting essentially of inert gases, depositing gases, and breakdown suppressing gases. The filled pore dielectric material is suitably used in a damascene wiring layer. In further embodiments, a plasma device comprises an integrated circuit (IC) chip substrate; at least one dielectric layer having a thickness on a surface of the substrate, a cavity formed in the dielectric layer, at least two electrodes disposed in the cavity; and a plasma gas filling the cavity. The plasma device can operate as a light source or as a switch.

### BACKGROUND OF INVENTION

The invention relates to semiconductor device fabrication, particularly to dielectric materials, and more particularly to dielectric materials used in conjunction with interconnect structures.

Semiconductor devices are typically joined together to form useful circuits using what is called “interconnect structures.” These interconnect structures typically comprise conductive materials such as copper (Cu) or aluminum (Al) and dielectric materials such as silicon dioxide (SiO₂). The speed of these interconnects can be roughly assumed to be inversely proportional to the product of the line resistance (R), and the capacitance (C) between lines. To reduce the delay and increase the speed, it is desirable to reduce the capacitance (C). This can be done by reducing the dielectric constant (k), of the dielectric material due to the relationship C=kξₒ(epsilonₒ) A/d, where ξₒ (epsilonₒ) is the permittivity of free space (a universal constant), A is the coupling area, and d is the distance between two conductors. Decreasing the dielectric constant (k) leads to a direct decrease in capacitance (C). Conventional silicon dioxide has a dielectric constant (k) of approximately 4.1. A variety of “low-k” materials are known, such as SiLK™, an organic polymer with k=2.65 sold by Dow Chemical., and Black Diamond™, a organosilicon glass with k of 2.7 to 3.0, sold by Applied Materials.

The dielectric constant (k) of a dielectric material may be decreased further by the introduction of porosity or holes within the dielectric. For example, “LKD 5109” is a spinon, porous (poly)methylsilsequioxane (MSSQ) material with k=2.2 sold by Japan Synthetic Rubber Corp. Taken to the extreme, it is known that “air gaps” or the absence of dielectric material can be used to build a semiconductor interconnect structure. A free space has k˜1.0, resulting in the lowest possible dielectric constant.

U.S. Pat. No. 6,472,740 (“Engel”) discloses a self-supporting air bridge interconnect structure for integrated circuits. A method for forming a multilevel interconnect structure for an integrated circuit is disclosed. In an exemplary embodiment of the invention, the method includes forming a starting structure upon a substrate, the starting structure having a number of metallic conducting lines (24) contained therein. A disk is bonded to the top of said starting structure, the disk including a plurality of mesh openings (52) contained therein. Air in voids (30) under the disk (50), between metallic conducting lines (24), may be left therein or evacuated to create a vacuum. Alternatively, the voids may be filled with a gas such as N₂, Ar, Xe, He, Kr or SF₆. The mesh openings may then filled with an insulative material, thereby forming a cap upon the starting structure, wherein the cap may structurally support additional interconnect layers subsequently formed thereatop. The disk (50) is described as having a thickness of about 10 nm-100 nm, and the openings (52) in the disk are described as having a size of about 50 nm-5 μm. As is evident from FIG. 3 therein, since a few openings (52) communicate with each void (30), the voids appear to have a cross-dimension of at least 10's or 100's of nanometers (nm). (1000 nm=1 μm)

FIG. 1 illustrates, in cross-section, an exemplary interconnect structure 100 of the prior art. An integrated circuit (IC) chip comprises a semiconductor substrate 102, and a number of conductive lines (conductor elements) 104 overlying an underlying layer 106. The conductive elements are in a “wiring layer”. The underlying layer 106 is merely illustrative—it may be an insulating layer, it may include semiconductor devices, interconnects, etc. Between each pair of adjacent conductive lines 104 there is a gap (void) 108.

A cap layer 110 is disposed atop the conductive lines 104, such as by being bonded to the top of the conductive lines 104. The cap layer 110 is essentially planar, and parallel to the surface of the substrate 102. The cap layer 110 has a number of openings (holes) 112 therein, extending therethrough. Typically, there is at least one hole 112 communicating with each one of the gaps 108. (One of the holes 112, the third from the left, is shown not plugged by 114, for illustrative clarity.)

Engel refers to a “multilevel interconnect structure”. The layer of conductive lines 104 is comparable to one level of such a multilevel interconnect structure. Engel refers to a “starting structure” which comprises a number of metallic conducting lines which are comparable to the conductive lines 104. Engel refers to a “disk” bonded to the top of the starting structure, Engel's disk is comparable to the cap layer 110. The cap layer 110 may structurally support additional interconnect layers subsequently formed thereatop.

As indicated in the aforementioned Engel patent, the gaps (referred to therein as “voids”) 108 may be filled with a gas such as N₂, Ar, Xe, He, Kr or SF₆. The cap (referred to therein as “mesh”) openings 112 may then filled with an insulative material. Herein, the holes 112 are plugged (sealed) by a dielectric (insulative) material 114, such a silicon nitride (Si₃N₄). In this manner, the cap closes the gaps 108, and the cap may structurally support additional interconnect layers subsequently formed thereatop. The gaps can be filled using a standard chemical vapor deposition (CVD) process and the appropriate gases.

A problem with using air gaps as insulators between conductive lines is that electrical arcing can occur in these gaps, and such electrical arcing reduces reliability and can result in device failure.

A similar problem would exist when using dielectric materials which have pores. Such pores may be difficult to avoid, or may be encouraged to exist, within these materials. When the pores are filled with air, they exhibit good dielectric properties, but these gaps also create sites with high electric fields which can actually arc, thus creating device defects or even failures. Examples of dielectric materials having pores include: organic materials, such as porous SiLK (tm, Dow); inorganic materials, such as nanoglass (tm, Honeywell); and organo-silicate materials, such as JSR LKD 5109 (a spin-on material, Japan Synthetic Rubber).

These materials have pores, usually (typically) ranging in size from 0.1 to 10 nanometers. The density of the pores, in other word how much of the material is pores versus the overall volume of the material, is typically approximately 20%-75% pores.

Light-emitting displays and other solid state displays are known. Such displays commonly require large glass plates and stand-alone circuitry. Typical display technologies are typically not compatible with CMOS technology.

On-chip switches—that is, switch components manufactured on an integrated circuit (IC) chip, along with other electronic components, are sometimes required in semiconductor applications; for example, radio frequency (RF) switching in IC chips used for cell phone applications. Known switching technology utilizes either a capacitive switch (usually good for high frequency components, but not low frequency) or a contact switch, which is usually good for low frequency transmission. However, contact switches built into integrated circuit devices suffer from problems such as short lifetimes and stiction (the phenomenon where in the moveable contact electrode remains “stuck” to the opposite electrode even when the actuation voltage is removed due to atomic-level roughness creating sufficient frictional barrier to prevent the return movement of the contacting electrode away from the contacted electrode). See, e.g., U.S. Pat. No. 6,635,506, entitled “Method of Fabricating Micro-Electromechanical Switches on CMOS Compatible Substrates”.

### SUMMARY OF INVENTION

It is an aspect of the invention to provide an improved dielectric material and an improved technique for forming interconnect structures for ICs chips.

According to the invention, a dielectric material comprises a matrix of a material selected from the group consisting of organic materials, inorganic materials and organo-silicate materials; a plurality of pores dispersed throughout the matrix; and a gas filling the pores, said gas selected from the group consisting of inert gases, depositing gases, and breakdown suppressing gases.

Further according to an aspect of the invention, the inert gases are selected from the group consisting of N₂, He, Ne, Kr, Xe, and Ar.

Still further according to an aspect of the invention, the inert gases are selected from the group consisting of Silane, MethylSilane, DiMethylSilane, TriMethylSilane, TetraMethylSi lane, TriEthoxySi lane, MethylTriEthoxySilane, DiEthoxyMethylSilane, DiMethoxyMethylSilane, TetramethyCycloTetraSiloxane, OctymethyCycloTetraSiloxane, and DiMethylDiMethoxySilane.

Yet further according to an aspect of the invention, the inert gas comprises SF₆.

Moreover according to an aspect of the invention, the dielectric material has a porosity of 20-70%, including 30-60%, 45-55% and approximately 50%. The size of the pores is 0.1-10 nm, including 0.5-5 nm, including approximately 1 nm.

According to the invention, a semiconductor substrate comprises a wiring layer, and the wiring layer comprises a dielectric material having filled pores and trenches formed in the dielectric material and filled with metal.

Moreover according to the invention, a wiring layer is formed on a wafer by depositing a dielectric material having pores; forming trenches in the dielectric material; and filling the trenches with metal. In one embodiment, after filling the trenches the wafer is heated and gas is flowed over the wafer to diffuse the gas into the pores. A dielectric layer may be deposited on the wiring layer to seal off exposed pores. In another embodiment, before filling the trenches the wafer is heated and gas is flowed over the wafer to diffuse the gas into the pores, and a sealing layer is deposited on a top surface of the wiring layer and in the trenches.

Further according to the invention, a plasma device comprises an integrated circuit (IC) chip substrate; at least one dielectric layer on a surface of the substrate, the dielectric layer having a thickness; a cavity formed in the dielectric layer, the cavity having a cross-dimension; at least two electrodes disposed in the cavity; and a plasma gas filling the cavity.

Also according to an aspect of the invention, the cavity of the plasma device has a cross-dimension of 1.0-25,000 microns. Also the cavity has a length “L”, a width “W”, and a height “H”. The length L is approximately 1-25 microns; the width W is approximately 1-25 microns; and the height H is approximately 1-1000 microns.

Still further according to an aspect of the invention, the electrodes in the plasma device are disposed on the bottom of the cavity.

Yet further according to an aspect of the invention, a capping layer is disposed atop the cavity.

Moreover according to an aspect of the invention, a sheet of quartz is disposed atop the capping layer.

Also according to an aspect of the invention, the at least two electrodes further comprise at least two ignition electrodes disposed in the cavity; and at least two switching electrodes disposed in the cavity.

### BRIEF DESCRIPTION OF DRAWINGS

The structure, operation, and advantages of the present invention will become further apparent upon consideration of the following description taken in conjunction with the accompanying figures (FIGS.). The figures are intended to be illustrative, not limiting. Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

FIG. 1 is a cross-sectional view of an interconnect structure showing filled air gaps between adjacent conductive lines, according to the prior art.

FIG. 2 is a schematic, cross-sectional view of an embodiment of a dielectric material having filled pores, according to the invention.

FIG. 2A is a cross-sectional view of an embodiment of a wiring layer comprising a dielectric material having filled pores, according to the invention.

FIG. 2B is a cross-sectional view of an embodiment of a wiring layer comprising a dielectric material having filled pores, according to the invention.

FIG. 3A is a perspective and FIG. 3B is a cross-sectional view of an embodiment of an on-chip light source device, according to the invention.

FIGS. 4A and 4B are top plan and side cross-sectional views, respectively of an embodiment of a glow discharge switch, according to the invention.

FIG. 4C is a schematic illustration of the switch of FIGS. 4A and 4B.

FIG. 5 is a schematic illustration of an alternate embodiment of a glow discharge switch, according to the invention.

### DETAILED DESCRIPTION

In the following description, numerous details are set forth in order to provide a thorough understanding of the present invention. It will be appreciated by those skilled in the art that variations of these specific details are possible while still achieving the results of the present invention. Well-known processing steps are generally not described in detail in order to avoid unnecessarily obfuscating the description of the present invention.

In the description that follows, exemplary dimensions are presented for an illustrative embodiment of the invention. The dimensions should not be interpreted as limiting. They are included to provide a sense of proportion. Generally speaking, it is the relationship between various elements, where they are located, their contrasting compositions, and sometimes their relative sizes that is of significance.

FIG. 2 illustrates a dielectric material having 200 having a “matrix” 202 (i.e., the material itself) and including a plurality of pores 204. The pores 204 are essentially uniformly distributed (dispersed) throughout the matrix and, like a sponge, are often in fluid communication with one another. This is shown by overlapping pores. The pores 204 may be stacked above each other, or may be not connected with one another (stand alone).

Dielectric materials having pores are known—for example: organic materials, such as porous SiLK (tm, Dow); inorganic materials, such as nanoglass (tm, Honeywell); and organo-silicate materials, such as JSR 5109 (tm Japan Synthetic Rubber). The pores 204 are filled with gasses, such as but not limited to: Xe, SF₆, Ar, SiH₄, Ne.

The pores 204 are filled with gas and sealed during CVD processing. The gasses are introduced during the initial portion of the CVD process and the CVD process itself will seal off the open pores, trapping the gasses inside.

CVD dielectric processes, such as thermal (APCVD, SACVD, thermal CVD), plasma enhanced, or high density plasma CVD, can be used to deposit dielectrics such as but not limited to: SiO₂, SiCOH, SiN, SiC, etc.

Alternatively, a CVD or PVD process may be used to seal the pores, with the gases used during the sputtering process being trapped within the pores. Metals or alloys, such as TaN, Ta, TiN, W, WN, TiSiN, etc., could be used.

The gases trapped within the pores of the dielectric material can: serve as an arc inhibitor; serve to raise the requirements for arcing to occur; should arcing occur, the gas can serve to seal the pore, thus “self-heal”; prevent other molecules from entering the void (i.e. H₂O); and
preserve the dielectric constant (k) by reducing the reactivity of the porous dielectric.

The elimination of arcing will generally improve reliability, especially early life failures where this type of failure mechanism usually occurs.

The pores can be filled with the following gases:
1. Inert Gases, such as but not limited to: N₂, He, Ne, Kr, Xe, Ar
2. Depositing Gases: such as but not limited to: Silane (SiH₄); 1MS, or MethylSilane (SiH₃(CH₃); 2MS, or DiMethylsilane (SiH₂(CH₃)₂); 3MS, or TriMethylsilane (SiH(CH₃)₃); 4MS, or TetraMethylSilane (SiH(CH₃)₄); TES, or TriEthoxySilane (SiH(CH₃CH₂O)₃)MTES, or MethylTriEthoxySilane (Si(CH₃CH₂)₃(CH₃); DEMS, or DiEthoxyMethylSilane (SiH(CH₃CH₂O)₂(CH₃); DMOMS, or DiMethoxyMethylSilane (SiH(CH₃O)₂(CH₃)); TMCTS, or TetramethyCycloTetraSiloxane OMCTS, or OctymethyCycloTetraSiloxane; DMDMOS, or DiMethylDiMethoxySilane (Si(CH₃)₂(CH₃O)₂).
3. Breakdown suppressing gases such as but not limited to: SF₆, etc.

Some of these gases may also be useful to form a plasma, in another embodiment of the invention, as described in greater detail herein below.

In Engel, discussed hereinabove, the voids (compare 108) between the conductive lines (compare 104) of the interconnect structure are macroscopic (e.g., tens to hundreds of nanometers), and are uniformly filled with either air or a gas. In this embodiment of the invention, pores 204 are microscopic (e.g., 0.1-10 nanometers, or 1-100 Angstroms). Regarding the porosity of the dielectric material 200—porosity being defined as how much of the material is pores, by volume—less than 20% pores is likely to result in the pores 204 not being interconnected with one another, thereby making it difficult to uniformly fill the pores with the gasses. And more than 75% pores can result in a loss of mechanical integrity for the dielectric, leading to brittleness and cracking. The porosity is 20-75%, including 30-60%, including 45-55%, including approximately 50%.

Regarding the size of the pores which is 0.1-10 namometers, above 10 nm (nanometers), there are issues of reliability, due to wire or via shorting through the pores. Below 0.1 nm (1 Angstrom) is on the atomic scale, and is not practical. Assuming a fairly uniform distribution of pore sizes, the average pore size is 0.1-10 nm, including 0.5-5 nm, including approximately 1 nm.

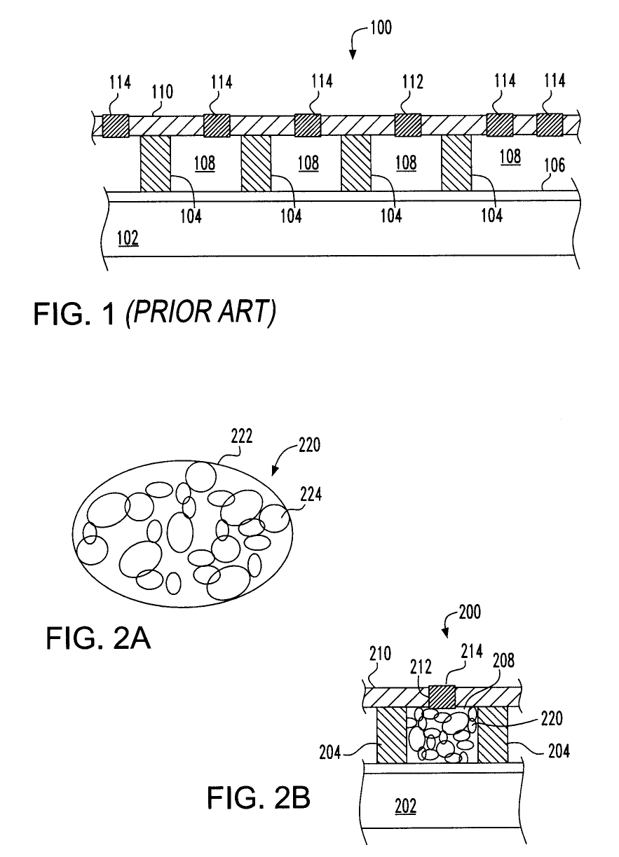

In an embodiment of the invention, the filled-pore dielectric material 200 of the present invention can be disposed in at least some (if not all) of the gaps 108 of the interconnect structure 100 of FIG. 1A.

FIG. 2A illustrates a substrate (wafer) 220 comprising a Damascene wiring layer. The wiring layer comprises a porous dielectric material 222, such as has been described hereinabove. (Pores omitted, for illustrative clarity.) The dielectric material 222 is deposited in any suitable manner, such as by spin-on followed by cure.

Trenches (Damascene vias) 224 are formed in the dielectric material and are filled with Damascene metal 226 (one trench is shown not filled, for illustrative clarity), and the top surface of the wiring layer is planarized, such as by chemical-mechanical polishing (CMP). Next, the wafer is heated, gas is flowed over the wafer and diffuses through the dielectric into the pores, and a dielectric layer 228 is deposited over the top of the wiring layer to seal off the exposed pores. In this manner, the porous dielectric layer 222 of a Damascene wiring layer has its pores filled with gasses, as described hereinabove with respect to the dielectric material 200 of FIG. 2.

FIG. 2B illustrates a substrate (wafer) 240 (compare 220) comprising a Damascene wiring layer 242 (compare 222). The wiring layer comprises a porous dielectric material, such as has been described hereinabove. (Pores omitted, for illustrative clarity.) Trenches (Damascene vias) 244 (compare 224) are formed in the wiring layer. Before filling the trenches with metal (compare above), the wafer is heated, gas is flowed over the wafer and diffuses through the dielectric into the pores, and a sealing layer 248 is deposited on the surface of the top surface of the wiring layer 242, as well as on the surfaces of the trenches 244. The sealing layer 248 may be a dielectric material (compare 228), or it may be a metal layer. The sealing layer 248 seals off the pores, as described above. After the pores are sealed off, standard damascene metallization (not shown, compare 226) is performed.

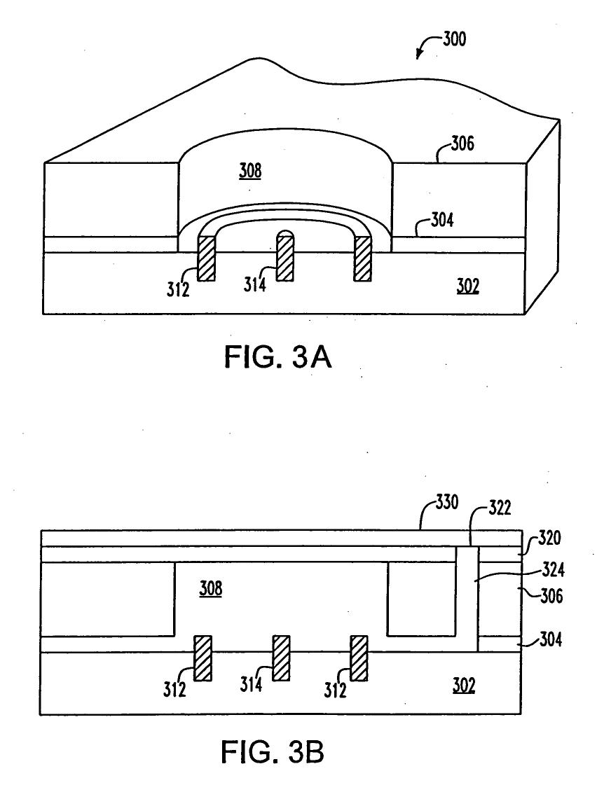

FIGS. 3A and 3B illustrate a first “active” embodiment of the invention wherein voids in a dielectric layer are filled with a gaseous material which will emit light (glow) when excited.

This embodiment is a “plasma device”. Generally, in a plasma device, a gas that is disposed between two electrodes is excited at a given frequency, and it gives off light (glows). The frequency can be 0 Hz (a DC signal). At the electrodes, there is a “sheath”, or dark space. The glow is between the electrodes.

FIG. 3A shows a single plasma device 300 of what may be a plurality or array of light sources fabricated on an integrated circuit (IC) chip. The plasma device includes a substrate 302 that has one or more dielectric layers 304, 306 built up upon its surface. A void or cavity 308 is formed in the dielectric layer 304. At least two electrodes (ignition electrodes) 312 and 314 are disposed in the cavity 308. As illustrated, one of the electrodes 312 is a cathode and extends around the periphery of the cavity 308 and the other of the electrodes 314 is an anode and is disposed centrally in the cavity. The anode and cathode may be reversed. FIG. 3A is merely illustrative of an embodiment.

The cavity 308 is shown as being round (in plan view), but is can have a different geometry, such as rectangular. The electrodes 312 and 314 are shown as being on the bottom of the cavity 308, but they may be disposed anywhere within the cavity. For example, they may be disposed on opposite sides of a rectangular cavity, in a manner comparable to a given pair of conductive lines 104 in FIG. 1 being disposed on opposite sides of a void 108.

As shown in FIG. 3B, the cavity 308 is capped by a transparent or translucent capping layer 320 (compare 110), which is covered by a thin sheet of quartz 330.

The cavity 308 is filled with a gas (“plasma gas”) which can form a plasma, such as N₂, Ar, Xe, He, Kr or SF₆. Alternatively, oxygen, or any gas or mixture known to be useful to provide a glow discharge to one skilled in the arts may be used to fill the cavity 308.

The cavity 308 may be filled in any suitable manner, such as by means of a hole 322 (compare 112) in the capping layer 320 which communicates with a passageway 324 extending through the dielectric layers 304, 306 into the cavity 308. The quartz sheet 330 seals the hole 322 (compare 114).

The cavity 308 has a cross-dimension which in the case of a round cavity is the diameter of the cavity, and a height which is essentially the thickness of the dielectric layers 304 and 306.

The cross-dimension of the cavity is 1.0-25,000 microns. Below 1 micron (1000 nm), it is not practical to cause the gas to glow, due to the “sheath” phenomenon discussed above, and 25,000 microns (25 mm) is a practical limitation of current lithography processes. In practice, the cross-dimension of a single cavity is suitably between 10 and 100 microns.

With a plurality of light sources 300 fabricated on an IC chip, a high density display can be made having a very large number of pixels. Such displays would be useful, among other things, for cell phones, hand held computing games, and the like. An advantage of the invention is that supporting circuitry can be incorporated onto the same IC chip as the light sources 300.

In this embodiment, the filled gap can be used to create a display of any type. In this case, a cavity is formed of arbitrary shape (from as simple as a “dot” to as complex as a serpentine pattern, or more complex). OLE_LINK1 Appropriate conditions (such as gas type, pressure, applied power frequency; voltage) OLE_LINK1 are chosen to encourage a plasma glow discharge within the cavity. Having a transparent material on “top” of the cavity allows the emission to exit from the cavity and to be used for any desired purpose. Selectively choosing the top material, such that it is transmissive at only certain wavelengths of light, allows for a desirable monochromatic output. The combination of multiple nearly co-located emission cavities of different transmission wavelengths can appear to the human eye as distinct “color” cells. Modulating the intensity of emission of different filled cavities can lead to the appearance of changing chromatic signatures.

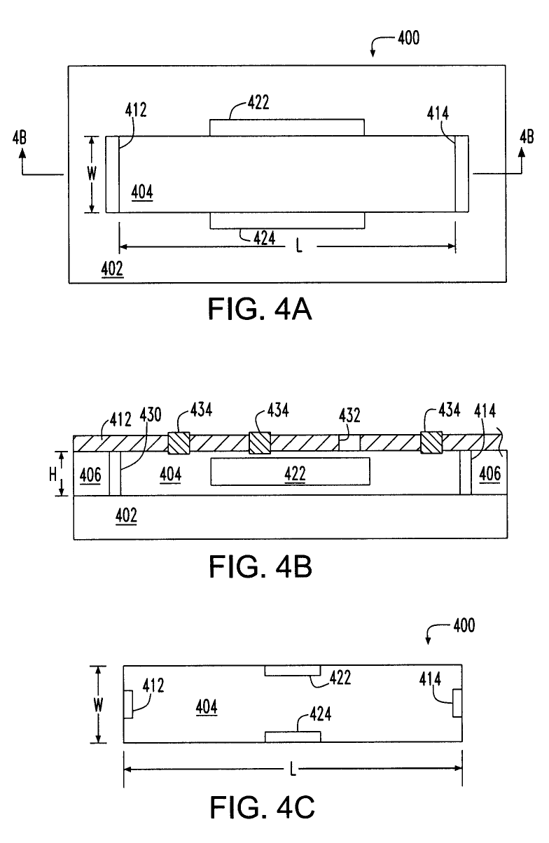

FIGS. 4A and 4B illustrate a plasma device that forms another “active” embodiment of the invention wherein air gaps filled with plasma gases are used as switching elements. A single switching element 400 is illustrated. Many of such switching elements 400 could be formed on a semiconductor substrate 402.

This embodiment is a “plasma device”. A plasma gas has insulating qualities when it is not excited. When it is excited, it glows (as described above), and it also becomes conductive.

The switching element 400 comprises a cavity 404 (compare 108) formed in a dielectric layer 406 on a substrate 402, two switching electrodes 412 and 414 disposed within the cavity 404 at opposite ends of the cavity 404, and two ignition electrodes 422 and 424 disposed within the cavity 404 on opposite sides of the cavity 404. The cavity 404 is shown as being rectangular (in plan view), having a length “L” and a width “W”, and also having a height “H”. It is 3-dimensional. In the view of FIG. 4B, the ignition electrode 422 is shown as having a height less than the height “H” of the cavity, 404, for illustrative clarity. It is not necessary that any of the electrodes have a height which is equal to the height “H” of the cavity. Typical dimensions for the cavity 404 are: L=approximately 1-25 microns; W=approximately 1-25 microns and; H=approximately 1-1000 microns.

A cap layer 430 (compare 110) is disposed atop the cavity 404, sealing off the cavity. The cap layer 430 is omitted from the view of FIG. 4A, for illustrative clarity. The cap layer 430 has at least one opening 432 (compare 112) disposed therein for filling the cavity 404 with gasses. The opening 432 can be sealed with a material 434 (compare 114) to retain the plasma gasses in the cavity 404.

The cavity 404 is filled with a gas (or gasses) which, in a “normal” (off) state, is non-conducting of electricity (i.e., a dielectric), and in an energized (on) state forms a plasma which is a conductor of electricity.

FIG. 4C illustrates the switch of FIGS. 4A and 4B in a schematic manner. No substrate is shown. Here it can be seen that the switching electrodes 412 and 414 are disposed at opposite ends of the cavity 404, and the ignition electrodes 422 and 424 are disposed on opposite sides of the cavity 404, between (inboard of) the switching electrodes 412 and 414.

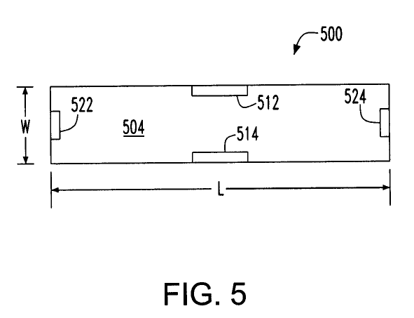

FIG. 5 illustrates an alternate embodiment of a switching element 500 (compare 400), in schematic form (compare FIG. 4C). Here, the plasma ignition electrodes 522 and 524 are disposed at the opposite ends of the cavity 504, and the switching electrodes 512 and 514 are disposed at the opposite sides of the cavity 504. This is believed to be a generally preferred arrangement over that of FIG. 4C, but with long life plasmas such as He plasma, disposing the plasma ignition electrodes 422 and 424 inboard of the switching electrodes 412 and 414 can be quite suitable.

When, as in FIG. 4C, the ignition electrodes 422 and 424 do not terminate the ends of the plasma cavity, time delays can be evoked that are controlled by the time it takes for the plasma to diffuse and connect the switch electrodes 412 and 414.

It is within the scope of the invention that there can be any number (greater than 2) of switch electrodes within the switch cavity, and that there can be any number (greater than 2) of ignition electrodes within the switch cavity. Such a device could be used as a time measurement technique to determine the speed at which a plasma propagates if these switches close a timing circuit. The device could also be used as a time-controlled switch—as the plasma propagation is somewhat constant for the same conditions, and thus the time to close the switches is a known constant delay.

Furthermore, in very large cavities not limited to but greater than 100 microns, it may be required that more than two ignition electrodes are required to initiate a plasma as the breakdown field may require an intermediate ignition electrode to maintain the required potential inside the cavity. This can be used to facilitate multiple circuits within a single plasma chamber.

With regard to light sources, multiple ignition electrodes could be used to sequence plasma discharges within the cavity to simulate movement (chasing lights), or for stroboscopic illumination in Micro-Electro-Mechanical Systems (MEMS) type devices.

The invention has been illustrated and described in a manner that should be considered as exemplary rather than restrictive in character it being understood that all changes and modifications that come within the scope of the invention as set forth in the claims.

1. A dielectric material comprising:
a matrix of a material selected from the group consisting of organic materials, inorganic materials and organo-silicate materials;
a plurality of pores dispersed throughout the matrix; and
a gas filling the pores, said gas selected from the group consisting of inert gases, depositing gases, and breakdown suppressing gases.

2. A dielectric material, according to claim 1, wherein the inert gases are selected from the group consisting essentially of N₂, He, Ne, Kr, Xe, and Ar.

3. A dielectric material, according to claim 1, wherein the depositing gases are selected from the group consisting essentially of Silane, MethylSilane, DiMethylSilane, TriMethylSilane, TetraMethylSilane, TriEthoxySilane, MethylTriEthoxySilane, DiEthoxyMethylSilane, DiMethoxyMethylSilane, TetramethyCycloTetraSiloxane, OctymethyCycloTetraSiloxane, and DiMethylDiMethoxySilane.

4. A dielectric material, according to claim 1, wherein the breakdown suppressing gases comprises SF₆.

5. A dielectric material, according to claim 1, wherein:
the dielectric material has a porosity of 20-70%.

6. A dielectric material, according to claim 1, wherein:
the dielectric material has a porosity of 30-60%.

7. A dielectric material, according to claim 1, wherein:
the size of the pores is 0.1-10 nm.

8. A dielectric material, according to claim 1, wherein:
the size of the pores is 0.5-5 nm.

9. A semiconductor substrate comprising a wiring layer, the wiring layer comprising:
a dielectric material having filled pores; and
trenches formed in the dielectric material and filled with metal.

10. A semiconductor substrate, according to claim 9, further comprising:
a dielectric layer disposed on the wiring layer.

11. A plasma device comprising:
an integrated circuit (IC) chip substrate;
at least one dielectric layer on a surface of the substrate, the dielectric layer having a thickness;
a cavity formed in the dielectric layer, the cavity having a cross-dimension;
at least two electrodes disposed in the cavity; and
a plasma gas filling the cavity.

12. A plasma device, according to claim 11, wherein:
the cross-dimension of the cavity is 1.0-25,000 microns.

13. A plasma device, according to claim 11, wherein:
the electrodes are disposed on the bottom of the cavity.

14. A plasma device, according to claim 11, further comprising:
a capping layer disposed atop the cavity.

15. A plasma device, according to claim 14, further comprising:
a sheet of quartz disposed atop the capping layer.

16. A plasma device, according to claim 11, wherein the at least two electrodes further comprises:
at least two ignition electrodes disposed in the cavity;
at least two switching electrodes disposed in the cavity.

17. A plasma device, according to claim 16, wherein:
the cavity has a length “L”, a width “W”, and a height “H”;
the length L is approximately 1-25 microns;
the width W is approximately 1-25 microns; and
the height H is approximately 1-1000 microns.

18. A plasma device, according to claim 16, wherein:
the switching electrodes are disposed at opposite ends of the cavity; and
the ignition electrodes are disposed on opposite sides of the cavity.

19. A plasma device, according to claim 16, wherein:
the switching electrodes are disposed at opposite sides of the cavity; and
the ignition electrodes are disposed on opposite ends of the cavity.
